(19) United States
(12) Patent Application Publication
(10) Pub. No.: US 2024/0258236 A1
(43) Pub. Date: Aug. 1, 2024

(54) SEMICONDUCTOR DEVICE

(71) Applicant: Socionext Inc., Kanagawa (JP)

(72) Inventors: Hirotaka TAKENO, Yokohama (JP); Atsushi OKAMOTO, Yokohama (JP); Wenzhen WANG, Yokohama (JP)

(21) Appl. No.: 18/608,113

(22) Filed: Mar. 18, 2024

Related U.S. Application Data
(63) Continuation of application No. PCT/JP2022/036487, filed on Sep. 29, 2022.
(60) Provisional application No. 63/261,846, filed on Sep. 30, 2021.

(51) Int. Cl. H01L 23/528; H01L 23/522

(52) U.S. Cl. CPC H01L 23/5286; H01L 23/5226

(57) ABSTRACT

A semiconductor device includes first and second power supply lines and first and second ground lines provided on a first surface of a substrate; a third power supply line provided on a second surface of the substrate, and connected to the first power supply line through a via; a fourth power supply line; a first area including the second power supply line, the first ground line, the third power supply line; a second area including the fourth power supply line and the second ground line; a third area positioned between the first area and the second area in plan view; and a power switch circuit including a switch transistor connected between the first power supply line and the second power supply line.

### CROSS-REFERENCE TO RELATED APPLICATIONS

This U.S. non-provisional application is a continuation application of and claims the benefit of priority under 35 U.S.C. § 365(c) from PCT International Application PCT/JP2022/036487 filed on Sep. 29, 2022, which is designated the U.S., and is based on and claims priority to U.S. provisional application No. 63/261,846 filed on Sep. 30, 2021, the entire contents of which are incorporated herein by reference.

### TECHNICAL FIELD

The present disclosure relates to semiconductor device.

### BACKGROUND ART

In an SRAM (Static Random Access Memory), in the case where arrangement of power supply lines is different between a bit cell area and a peripheral circuit area, in some cases, a separating area is provided to secure spacing between the bit cell area and the peripheral circuit area in plan view. A technique called BPR (Buried Power Rails) has been known, in which the power supply lines are buried in a semiconductor substrate. In order to switch between supply and cutoff of a power supply voltage to a virtual power supply line of an internal circuit, a technique that provides a power switch circuit between a power supply line and the virtual power supply line has been known. A technique called BS-PDN (Backside-Power Delivery Network) has been known in which a power supply line network is provided on the back surface of a semiconductor substrate, and a power supply voltage is supplied through a via that penetrates the back surface and the top surface of the semiconductor substrate.

### RELATED ART DOCUMENTS

### Patent Documents

[Patent Document 1] U.S. Pat. No. 10,446,224
[Patent Document 2] U.S. Pat. No. 8,670,265
[Patent Document 3] US Patent Publication No. 2020/0135718
[Patent Document 4] US Patent Publication No. 2018/0151494
[Patent Document 5] US Patent Publication No. 2005/0212018
[Patent Document 6] U.S. Pat. No. 10,170,413
[Patent Document 7] WO2020/065916
[Patent Document 8] WO2021/070366
[Patent Document 9] WO2021/070367
[Patent Document 10] WO2021/079511
[Patent Document 11] WO2021/111604

In the case where a BS-PDN is provided on the back surface of the substrate, detailed technical studies on how to arrange the power switch circuit have not been carried out.

### SUMMARY

According to one aspect in the present disclosure, the semiconductor device includes a substrate including a first surface and a second surface opposite to the first surface; a first power supply line provided on the first surface; a second power supply line provided on the first surface; a first ground line provided on the first surface; a third power supply line provided on the second surface; a via provided on the substrate and electrically connecting the first power supply line and the third power supply line; a fourth power supply line electrically connected to the second power supply line; a second ground line provided on the first surface; a first area including the second power supply line, the first ground line, the third power supply line, and the via; a second area including the fourth power supply line and the second ground line; a third area positioned between the first area and the second area in plan view; and a power switch circuit including a switch transistor electrically connected between the first power supply line and the second power supply line.

### BRIEF DESCRIPTION OF DRAWINGS

FIG. 1 is a plan view illustrating an overview of a layout of a semiconductor device in a first embodiment;

FIG. 2 is a circuit block diagram illustrating an overview of a power switch circuit arranged in a bit cell area in FIG. 1;

FIG. 3 is a plan view illustrating an example of a layout of power supply lines in an area where a power switch circuit in FIG. 1 is arranged;

FIG. 4 is a plan view illustrating another example of a layout of power supply lines in an area where the power switch circuit in FIG. 1 is arranged;

FIG. 5 is a diagram illustrating an example of a bit cell arranged in the bit cell area in FIG. 1;

FIG. 6 is a diagram illustrating another example of a bit cell arranged in the bit cell area in FIG. 1;

FIG. 7 is a plan view illustrating an example of a layout of the power switch circuit, the bit cell area, and the peripheral circuit area in FIG. 3;

FIG. 8 is a cross-sectional view illustrating a cross section along a line Y1-Y1′ in FIG. 7;

FIG. 9 is a cross-sectional view illustrating a cross section along a line Y2-Y2′ in FIG. 7;

FIG. 10 is a plan view illustrating a modified example of the layout illustrated in FIG. 7;

FIG. 11 is a plan view illustrating an example of a layout of power supply lines in an area where a power switch circuit of a semiconductor device in a second embodiment is arranged;

FIG. 12 is a plan view illustrating an example of a power switch circuit arranged in the peripheral circuit area in FIG. 11;

FIG. 13 is a plan view illustrating a modified example of a power switch circuit in FIG. 11;

FIG. 14 is a circuit block diagram illustrating an overview of a power switch circuit arranged in a standard cell area of a semiconductor device in a third embodiment;

FIG. 15 is a plan view illustrating an overview of a layout of a standard cell area in FIG. 14;

FIG. 16 is a plan view illustrating an example of a layout of power supply lines in an area where the power switch circuit in FIG. 15 is arranged;

FIG. 17 is a plan view illustrating an example of a power switch circuit in FIG. 16;

FIG. 18 is a plan view illustrating an example of an end cap cell PSW-EN2 in FIG. 15;

FIG. 19 is a plan view illustrating an example of a case where the end cap cell in FIG. 18 is arranged to be adjacent to the power switch circuit in FIG. 17; and

FIG. 20 is a plan view illustrating an example of an end cap cell PSW-EN1 in FIG. 15.

### DESCRIPTION OF EMBODIMENTS

In the following, embodiments will be described with reference to the drawings.

According to the disclosed techniques, a power supply switch can be appropriately arranged in a semiconductor device having a substrate in which a power supply line network is provided on the back surface.

In the following, a reference numeral denoting a signal may also be used for denoting a signal value, a signal line, or a signal terminal. A reference numeral denoting a power supply may also be used for denoting a power supply voltage, a power supply line or a power supply terminal to which the power supply voltage is supplied.

### First Embodiment

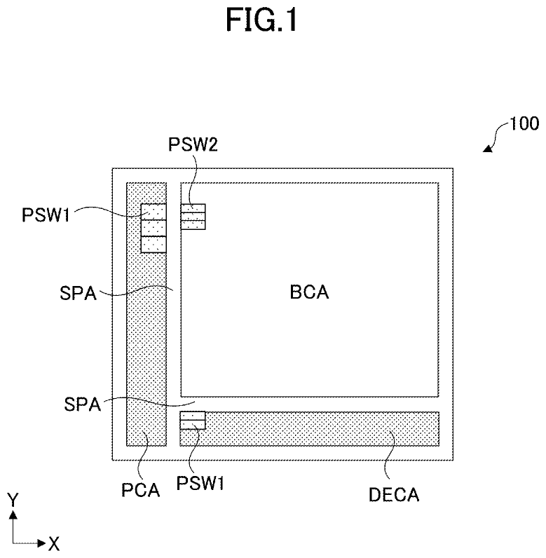

FIG. 1 is a plan view illustrating an overview of a layout of a semiconductor device in a first embodiment. A semiconductor device 100 illustrated in FIG. 1 is, for example, an SRAM. The semiconductor device 100 includes a bit cell area BCA, and a peripheral circuit area PCA and a decoder area DECA arranged peripheral to the bit cell area BCA. The peripheral circuit area PCA and the decoder area DECA constitute an example of a first area. The bit cell area BCA is an example of a second area.

For example, the peripheral circuit area PCA and the bit cell area BCA are arranged side by side in the X direction, and the decoder area DECA and the bit cell area BCA are arranged side by side in the Y direction. The X direction is an example of a first direction. The Y direction is an example of a second direction different from the first direction. In plan view, the separating area SPA is arranged between the bit cell area BCA, the peripheral circuit area PCA, and the decoder area DECA. The separating area SPA is an example of a third area.

For example, respective power supply voltages different from each other are supplied to the bit cell area BCA, the peripheral circuit area PCA, and the decoder area DECA. For example, multiple power supply lines extending in the X direction and arranged side by side in the Y direction are arranged in the bit cell area BCA, the peripheral circuit area PCA, and the decoder area DECA. Note that the positions and arrangement spacing of the power supply lines in the bit cell area BCA, the peripheral circuit area PCA, and the decoder area DECA may be different from one another. In addition, the power supply voltage may be commonly supplied to the bit cell area BCA and the peripheral circuit area PCA.

In addition, each of the peripheral circuit area PCA and the decoder area DECA is provided with a predetermined number of power switch circuits PSW1. The bit cell area BCA is provided with a predetermined number of power switch circuits PSW2. Note that one or both of the power switch circuits PSW1 and PSW2 may be arranged in the separating area SPA. The power switch circuit PSW1 is an example of a first power switch circuit. The power switch circuit PSW2 is an example of a second power switch circuit. In the following, in the case where the power switch circuits PSW1 and PSW2 are referred to without distinction, these circuits may also be referred to as the power switch circuit(s) PSW.

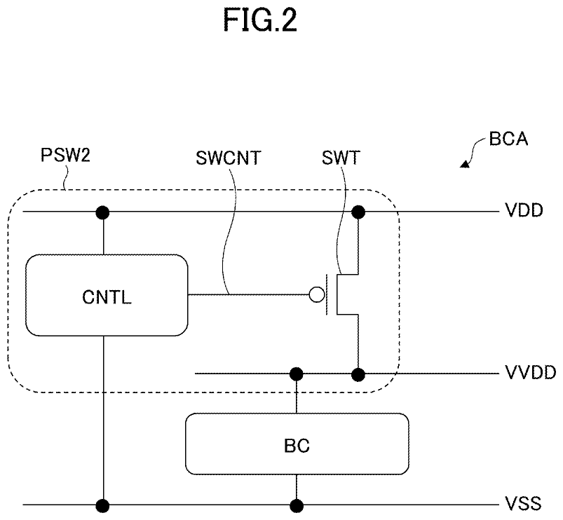

FIG. 2 is a circuit block diagram illustrating an overview of the power switch circuit PSW2 arranged in the bit cell area BCA in FIG. 1. Note that the power switch circuit PSW1 arranged in the peripheral circuit area PCA and the decoder area DECA also has substantially the same circuit configuration as in FIG. 2. The bit cell area BCA has multiple bit cells BC (i.e., memory cells). Each bit cell BC is electrically connected to the virtual power supply line VVDD and the ground line VSS, and operates by receiving power from the virtual power supply line VVDD.

The power switch circuit PSW2 includes a switch transistor SWT and a control circuit CNTL. The switch transistor SWT is, for example, a p-channel transistor, and operates by receiving at the gate a switch control signal SWCNT from the control circuit CNTL. Note that although one switch transistor SWT is illustrated in FIG. 2 for the sake of simplification, multiple switch transistors SWT may be arranged between the power supply line VDD and the virtual power supply line VVDD.

While the switch transistor SWT is on, the power supply line VDD and the virtual power supply line VVDD are electrically connected, and the power supply voltage VDD is supplied to the virtual power supply line VVDD. While the switch transistor SWT is off, the electrical connection between the power supply line VDD and the virtual power supply line VVDD is cut off, and the virtual power supply line VVDD is set to a floating state.

The control circuit CNTL is, for example, a buffer circuit. In the case of causing the SRAM to operate, the control circuit CNTL sets the switch control signal SWCNT to a low level, to supply the power supply voltage from the power supply line VDD to the virtual power supply line VVDD. In the case of causing the SRAM to stop operating, the control circuit CNTL sets the switch control signal SWCNT to a high level to stop supplying the power supply voltage from the power supply line VDD to the virtual power supply line VVDD.

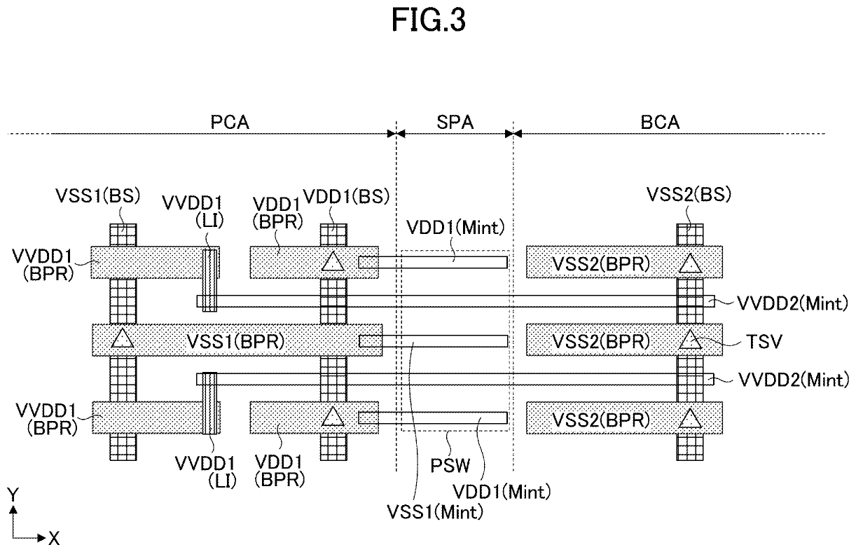

FIG. 3 is a plan view illustrating an example of a layout of power supply lines in an area where the power switch circuit PSW in FIG. 1 is arranged. FIG. 3 is an enlarged view of an area in which the peripheral circuit area PCA and the bit cell area BCA are arranged to have the separating area SPA sandwiched in-between, and the power switch circuits PSW1 and PSW2 in FIG. 1 are arranged in the separating area SPA as a common power switch circuit PSW. Note that as illustrated in FIG. 1, the power switch circuits PSW1 and PSW2 may be provided in the peripheral circuit area PCA and the bit cell area BCA, respectively.

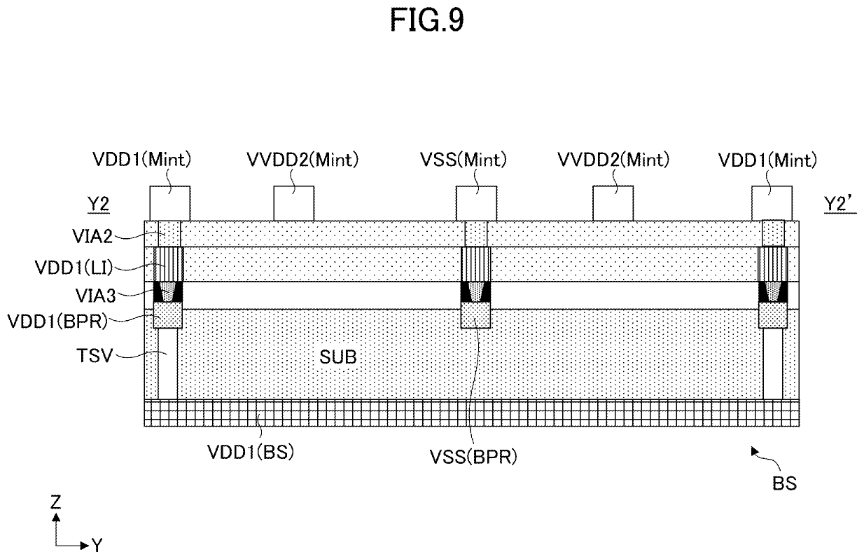

In the example illustrated in FIG. 3, interconnects of a Mint layer and interconnects of BPR are provided respectively extending in the X direction, and local interconnects LI and interconnects of the back surface BS of the semiconductor substrate SUB (FIG. 9) are provided respectively extending in the Y direction. For example, the Mint layer is provided on the top surface of the semiconductor substrate SUB, and is a metal interconnect layer closest to the semiconductor substrate SUB. The local interconnects LI are provided on the semiconductor substrate SUB side relative to the Mint layer. The semiconductor substrate SUB is an example of a substrate. The top surface of the semiconductor substrate SUB is an example of a first surface, and the back surface of the semiconductor substrate SUB is an example of a second surface opposite to the top surface of the semiconductor substrate SUB.

In the following, a power supply line, a virtual power supply line, and a ground line routed in the peripheral circuit area PCA and the decoder area DECA are denoted by reference numerals VDD1, VVDD1, and VSS1, respectively. A power supply line, a virtual power supply line, and a ground line routed in the bit cell area BCA are denoted by reference numerals VDD2, VVDD2, and VSS2, respectively. In addition, in the following, reference numerals BPR, LI, Mint, and BS in parentheses after a power supply line name or ground line name indicate the layer in which the corresponding power supply line or ground line is provided. Note that in FIG. 3, the virtual power supply line VVDD2(Mint) extends to the peripheral circuit area PCA.

A circuit arranged in the peripheral circuit area PCA and the decoder area DECA is electrically connected to the virtual power supply line VVDD1 and the ground line VSS1. A bit cell arranged in the bit cell area BCA is electrically connected to the virtual power supply line VVDD2 and the ground line VSS2. In the example illustrated in FIG. 3, the power switch circuit PSW is electrically connected to the power supply line VDD1, the virtual power supply line VVDD2, and the ground line VSS1.

The separating area SPA is provided with the power switch circuit PSW that includes a switch transistor (not illustrated) electrically connected to the power supply line VDD1(Mint) and the virtual power supply line VVDD2(Mint). The power switch circuit PSW is electrically connected to the ground line VSS1(Mint).

In the separating area SPA, the power supply line VDD1(Mint) is connected to the power supply line VDD1(BPR) provided in the peripheral circuit area PCA. The ground line VSS1(Mint) is connected to the ground line VSS1(BPR) provided in the peripheral circuit area PCA. The power supply voltage supplied to the virtual power supply line VVDD2(Mint) through the power switch circuit PSW is supplied to the bit cell area BCA and supplied to the peripheral circuit area PCA through the virtual power supply lines VVDD1(LI) and VVDD1(BPR).

In the bit cell area BCA, the ground line VSS2(BPR) provided on the top surface of the semiconductor substrate SUB and the ground line VSS2(BS) provided on the back surface BS of the semiconductor substrate SUB are connected to each other through a TSV (Through Silicon Via). The TSV is an example of a via. In the peripheral circuit area PCA, the ground line VSS1(BPR) provided on the top surface of the semiconductor substrate SUB and the ground line VSS1(BS) provided on the back surface BS of the semiconductor substrate SUB are connected to each other through the TSV. In addition, in the peripheral circuit area PCA, the power supply line VDD1(BPR) and the ground line VDD1(BS) provided on the back surface BS are connected to each other through the TSV.

Note that the ground lines VSS1 and VSS2 may be connected to each other through interconnects provided on the back surface BS or the top surface of the semiconductor substrate SUB. In the following, the back surface BS of the semiconductor substrate SUB may also be simply referred to as the back surface BS.

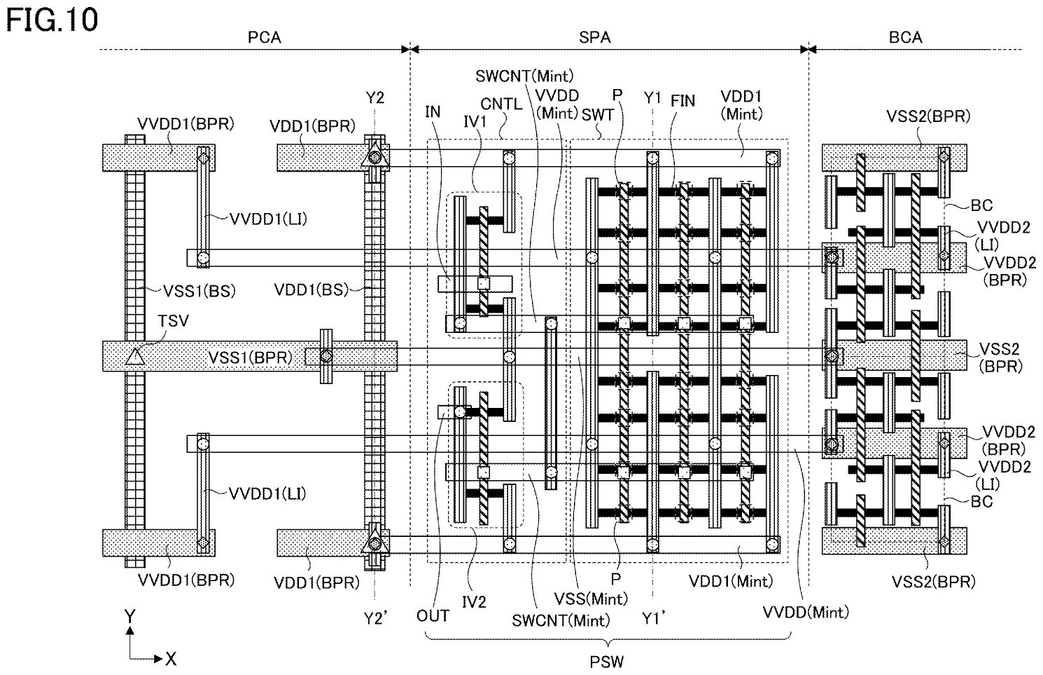

In addition, in FIG. 3, although the virtual power supply line VVDD2 of the bit cell area BCA is provided in the Mint layer, the line may be provided using the BPR as illustrated in FIG. 10 that will be described later. In this case, the virtual power supply line VVDD2(BPR) and the virtual power supply line VVDD2(BS) provided on the back surface BS may be connected to each other through the TSV. In addition, the virtual power supply line VVDD2(BS) provided on the back surface BS may be connected to the virtual power supply line VVDD2(Mint) through the TSV.

The power supply line VDD1(BPR) is an example of a first power supply line. The virtual power supply line VVDD1(BPR) is an example of a second power supply line. The power supply line VDD1(BS) is an example of a third power supply line. The power supply line VDD1(Mint) is an example of a fifth power supply line. The virtual power supply line VVDD2(Mint) is an example of a fourth power supply line or a sixth power supply line. The ground line VSS1(BPR) is an example of a first ground line. The ground line VSS2(BPR) is an example of a second ground line. The ground line VSS1(BS) is an example of a third ground line. The ground line VSS2(BS) is an example of a fourth ground line. For example, the power supply line VDD1(BS), the ground line VSS1(BS), the virtual power supply line VVDD2(BS) and the ground line VSS2(BS) may be provided as a BS-PDN.

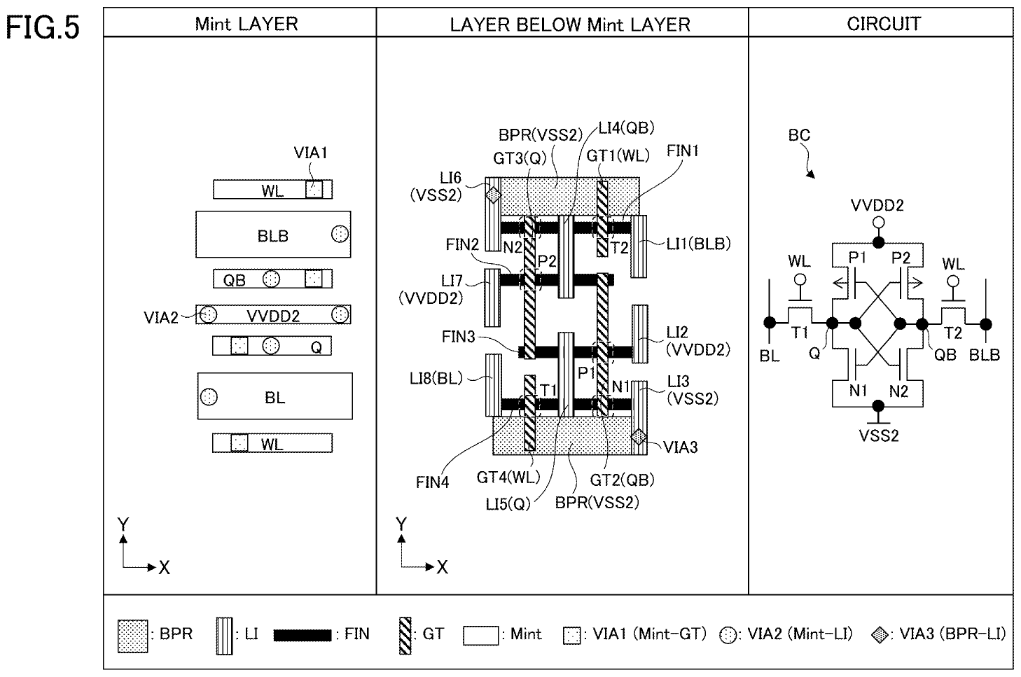

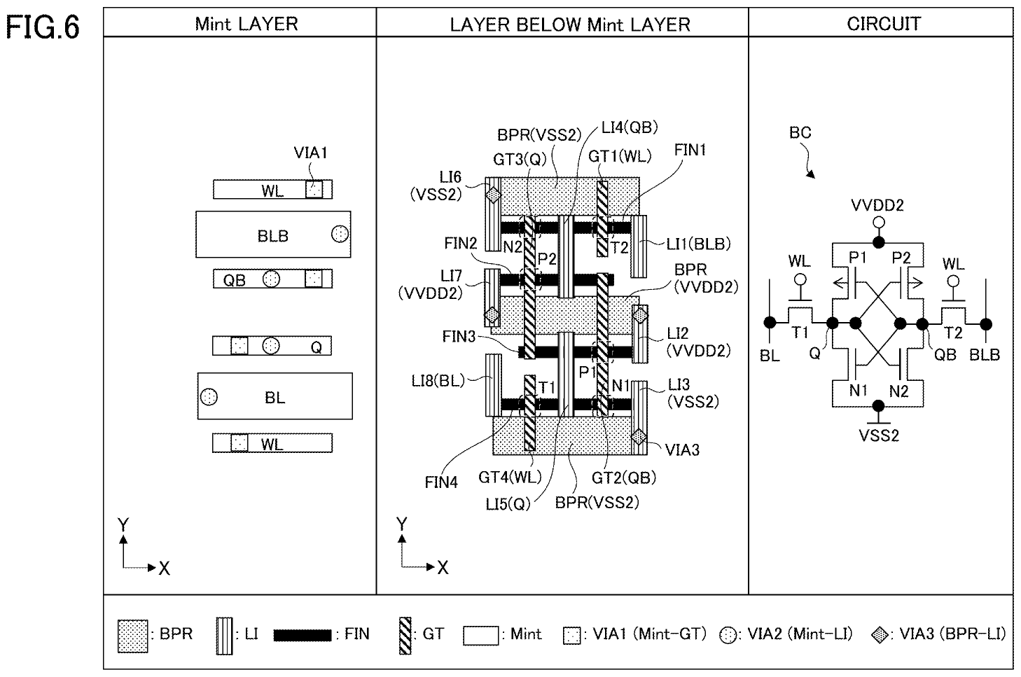

For example, the layout illustrated in FIG. 3 is arranged repeatedly in the Y direction. In the bit cell area BCA in which a large number of bit cells BC (FIG. 5 or FIG. 6) are arranged, elements such as transistors may be arranged more densely than in the peripheral circuit area PCA. Therefore, corresponding to the elements arranged at a higher density, the arrangement spacing of the ground lines VSS2(BPR) in the Y direction may be set smaller than the arrangement spacing of the ground lines VSS1(BPR) of the peripheral circuit area PCA in the Y direction.

Therefore, in the peripheral circuit area PCA and the bit cell area BCA, the types of power supply lines of the BPRs arranged side by side in the X direction may or may not be the same as each other. In consideration of the case where the types of power supply lines of the BPRs arranged side by side in the X direction are different (e.g., VDD1 and VSS2), the spacing of the interconnects of the BPRs in the X direction is set to a distance that is less likely to be mutually affected by the power supply, for example, by layout rules.

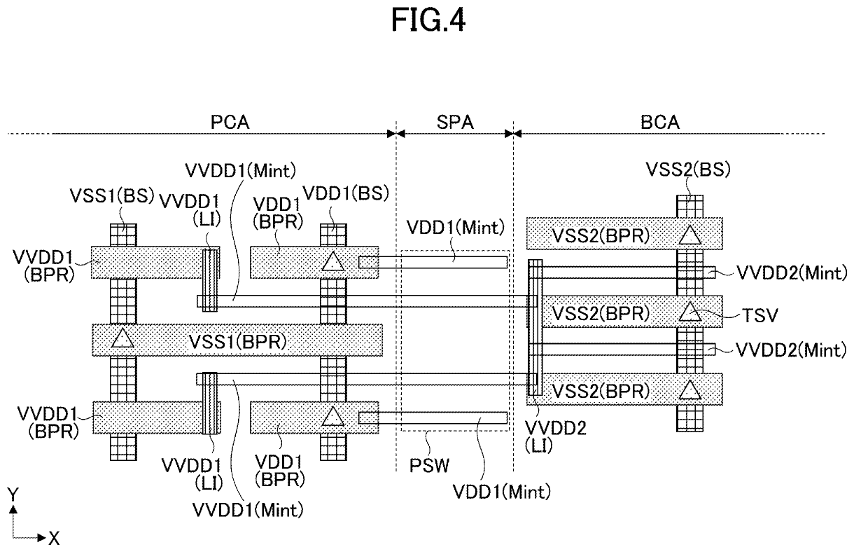

FIG. 4 is a plan view illustrating another example of a layout of power supply lines in an area where the power switch circuit in FIG. 1 is arranged. Elements that are substantially the same as in FIG. 3 are assigned the same reference numerals or the same patterns, and detailed description thereof is omitted.

In FIG. 4, the positions of the interconnects of the BPR provided in the peripheral circuit area PCA and the interconnects of the BPR provided in the bit cell area BCA are different from each other in the Y direction. In addition, the positions of the virtual power supply lines VVDD1(Mint) provided in the peripheral circuit area PCA and the separating area SPA, and the virtual power supply lines VVDD2(Mint) provided in the bit cell area BCA are different from each other in the Y direction.

In this case, the virtual power supply lines VVDD1(Mint) are electrically connected to the virtual power supply lines VVDD2(Mint) through the local interconnect LI extending in the Y direction in the bit cell area BCA. Accordingly, the virtual power supply lines VVDD1(Mint) and the VVDD2(Mint) having different positions in the Y direction can be connected to each other, and the power switch circuit PSW provided in the separating area SPA can be shared between the peripheral circuit area PCA and the bit cell area BCA. The virtual power supply line VVDD1(Mint) is an example of a first interconnect. Note that an interconnect extending in the Y direction that electrically connects the virtual power supply lines VVDD1(Mint) and the virtual power supply lines VVDD2(Mint) may be an interconnect provided in a layer above the Mint layer.

FIG. 5 is a diagram illustrating an example of the bit cell BC arranged in the bit cell area BCA in FIG. 1. In order to make it easier to understand the layout of interconnects, the left box in FIG. 5 illustrates a layout of interconnects in the Mint layer and vias connected to the Mint layer, and the middle box in FIG. 5 illustrates a layout of interconnects, gates, fins, and vias in a layer below the Mint layer (on the semiconductor substrate SUB side). In addition, the right box in FIG. 5 illustrates a circuit of the bit cell BC. The layouts illustrated in the left and middle boxes in FIG. 5 are positioned to overlap each other in plan view. Note that in FIG. 5, a power supply line name, a ground line name, a signal line name, or a node name are shown in parentheses added after an interconnect layer name or a gate name.

A via VIA1 illustrated as a square connects an interconnect in the Mint layer to a corresponding gate. A via VIA2 illustrated as a circle connects an interconnect in the Mint layer to a local interconnects LI. A via VIA3 illustrated as a diamond connects a local interconnect LI to an interconnect of the BPR. A local interconnect LI and a fin FIN are connected at positions that overlap in plan view.

Rectangular dashed lines illustrated in the middle box in FIG. 5 indicate p-channel transistors P1 and P2, n-channel transistors N1 and N2, and transfer transistors T1 and T2. The transfer transistors T1 and T2 are n-channel transistors. Reference numerals Q and QB illustrated in the left, middle, and right boxes in FIG. 5 indicate complementary storage nodes of the bit cell BC. A storage node Q is connected to a bit line BL through the transfer transistor T1. A storage node QB is connected to a bit line BLB through the transfer transistor T2.

Two word lines WL provided in the Mint layer are connected to gates GT4 and GT1 of the transfer transistors T1 and T2 through the vias VIA1, respectively. A virtual power supply line VVDD2 provided in the Mint layer is connected to local interconnects LI2 and LI7 through the vias VIA2. The local interconnect LI2 is connected to the source of the p-channel transistor P1. The local interconnect LI7 is connected to the source of the p-channel transistor P2.

An interconnect Q provided in the Mint layer is connected to a local interconnect LI5 and fins FIN3 and FIN4 through the via VIA2, and to a gate GT3 through the via VIA1. The fin FIN3 functions as the source and the drain of the p-channel transistor P1, and the fin FIN4 functions as the source and the drain of the transfer transistor T1 and the n-channel transistor N1.

An interconnect QB provided in the Mint layer is connected to a local interconnect LI4 and fins FIN2 and FIN1 through the via VIA2, and to a gate GT2 through the via VIA1. The fin FIN2 functions as the source and the drain of the p-channel transistor P2, and the fin FIN1 functions as the source and the drain of the transfer transistor T2 and the n-channel transistor N2.

The bit line BLB provided in the Mint layer is connected to the local interconnect LI1 and the fin FIN1 through the via VIA2. The bit line BL provided in the Mint layer is connected to the local interconnect LI8 and the fin FIN4 through the via VIA2. The ground lines VSS2 of the two BPR arranged on both sides in the Y direction in the middle box in FIG. 5 are connected to the local interconnects LI3 and LI6 through the vias VIA3, respectively. The local interconnect LI3 is connected to the source of the n-channel transistor N1. The local interconnect LI6 is connected to the source of the n-channel transistor N2.

FIG. 6 is a diagram illustrating another example of the bit cell BC arranged in the bit cell area BCA in FIG. 1. Elements that are substantially the same as in FIG. 5 are assigned the same reference numerals or the same patterns, and detailed description thereof is omitted. FIG. 6 illustrates substantially the same layouts as FIG. 5 except that the virtual power supply line VVDD2 is also provided in the BPR.

The virtual power supply lines VVDD2 of the local interconnects LI2 and LI7 are connected to the virtual power supply line VVDD2 of the BPR through the vias VIA3. The virtual power supply line VVDD2 of the BPR is arranged between the ground lines VSS2 of the two BPR, and extends in the X direction, similar to the ground lines VSS2 of the two BPR.

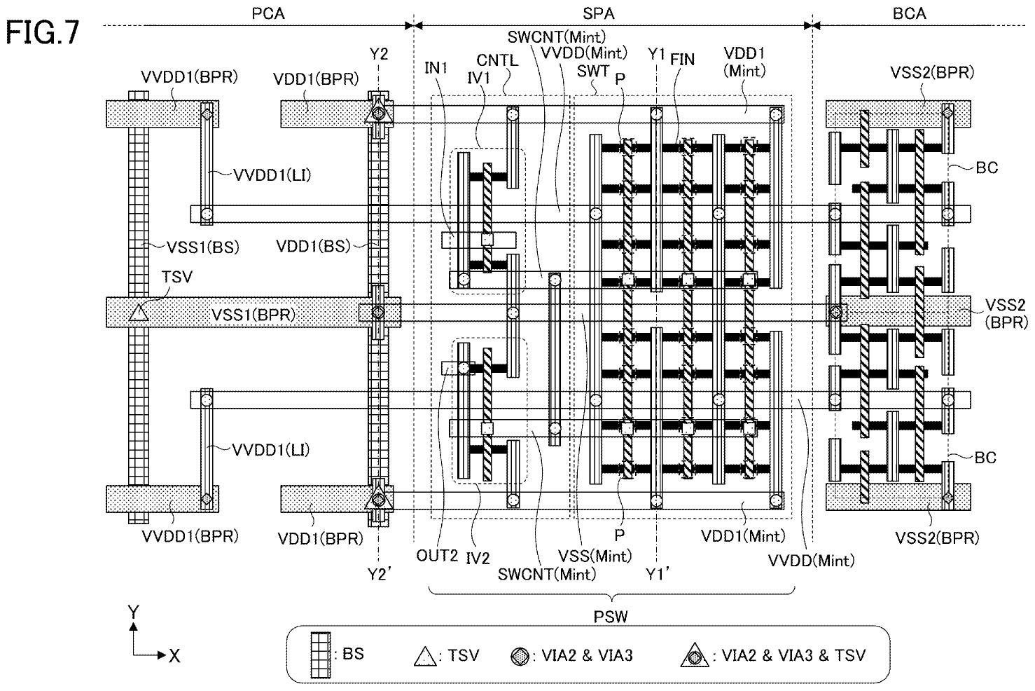

FIG. 7 is a plan view illustrating an example of a layout of the power switch circuit PSW, the bit cell area BCA, and the peripheral circuit area PCA in FIG. 3. Among legends illustrating correspondence between interconnect patterns and interconnect types illustrated in FIG. 7, those not illustrated in FIG. 7 are the same as the legends illustrating the correspondence between interconnect patterns and interconnect types illustrated in FIGS. 5 and 6.

For example, the bit cells BC illustrated in FIG. 5 are arranged side by side in the Y direction in the bit cell area BCA. At this time, two bit cells BC arranged in the Y direction are arranged in mirror symmetry with the X direction as the axis. Note that in FIG. 7, part of the interconnects and vias of the bit cell area BC are not illustrated.

The power switch circuit PSW arranged in the separating area SPA includes the switch transistor SWT and the control circuit CNTL illustrated in FIG. 2. The control circuit CNTL includes inverters IV1 and IV2 connected to the power supply line VDD1(Mint) and the ground line VSS(Mint). The inverters IV1 and IV2 operate as buffers. The inverter IV1 inverts the level of a signal received at the input terminal IN, and outputs the inverted signal to a switch control signal line SWCNT(Mint) as a switch control signal SWCNT. For example, the ground line VSS(Mint) routed to the separating area SPA is connected to the ground line VSS1(BPR) of the peripheral circuit area PCA and the ground line VSS2(BPR) of the bit cell area BCA.

The switch control signal SWCNT is supplied to the gate of the p-channel transistor P of the switch transistor SWT and the input terminal of the inverter IV2. The inverter IV2 inverts the level of a signal received at the input terminal and outputs the inverted signal from the output terminal OUT. For example, a signal output from the output terminal OUT2 is supplied to the input terminal IN2 of the control circuit CNTL of the other power switch circuit PSW (not illustrated) arranged to be adjacent to the power switch circuit PSW in the Y-direction illustrated in FIG. 7. The switch control signal SWCNT controls on and off of the p-channel transistor P of the switch transistor SWT, and controls supply of the power supply voltage to the virtual power supply line VVDD.

The switch transistor SWT includes multiple p-channel transistors P each of which has the source connected to the power supply line VDD1(Mint), the drain connected to the virtual power supply line VVDD(Mint), and the gate connected to the switch control signal line SWCNT(Mint). Here, the source of the p-channel transistor P is provided on one of fins FIN opposite to each other and having a gate sandwiched in-between. The drain of the p-channel transistor P is provided on the other of the fins FIN opposite to each other and having the gate sandwiched in-between.

The one of the fins FIN is electrically connected to the power supply line VDD1(Mint) through the local interconnect LI, and the other of the fins FIN is electrically connected to the virtual power supply line VVDD(Mint) through the local interconnect LI. The virtual power supply line VVDD(Mint) connected to the switch transistor SWT extends along the X direction to the peripheral circuit area PCA, to be connected to the virtual power supply line VVDD1(BPR) through the local interconnect LI of the peripheral circuit area PCA. In addition, the virtual power supply line VVDD(Mint) extends along the X direction to the bit cell BC, to be connected to the bit cell BC.

The peripheral circuit area PCA is provided with multiple power supply lines VDD1(BPR) connected to the power supply line VDD1(Mint). The multiple power supply lines VDD1(BPR) are connected to the power supply line VDD1(BS) of the back surface BS through the TSV. By electrically connecting the power supply line VDD1(BS) to the multiple power supply lines VDD1(BPR) in common and providing the power supply lines VDD1 in a mesh shape, the power supply capability can be increased.

In addition, the peripheral circuit area PCA is provided with multiple ground lines VSS1(BPR) connected to the ground line VSS1(Mint). The multiple ground lines VSS1(BPR) are connected to each other through the ground line VSS1(BS) of the back surface BS through the TSV. By electrically connecting the ground line VSS1(BS) to the multiple ground lines VSS1(BPR) in common, the ground lines VSS1 can be provided in a mesh shape, the ground resistance can be reduced, and the power supply noise can be reduced.

By having the virtual power supply line VVDD(Mint) extending along the X direction extended along the X direction, the power supply voltage output from the drain of the switch transistor SWT can be supplied to the peripheral circuit area PCA and the bit cell area BCA. Here, the virtual power supply line VVDD(Mint) can be routed without any folding in plan view.

By having the ground line VSS(Mint) extending along the X direction extended along the X direction, the ground line VSS can be connected to the ground line VSS1(BPR) and ground line VSS1(BS) of the peripheral circuit area PCA and the ground line VSS2(BPR) of the bit cell BC. Accordingly, compared with the case where the ground line VSS(Mint) connected to the power switch circuit PSW is connected to only either one of the peripheral circuit area PCA or the bit cell area BCA, the ground resistance can be reduced.

Note that the interconnects of the BPR of the bit cell area BCA and the interconnects of the BPR of the peripheral circuit area PCA may be arranged to be shifted in the Y direction as illustrated in FIG. 4. In addition, as illustrated in FIG. 4, multiple ground lines VSS2(BPR) of the bit cell area BCA may be connected to each other through ground lines VSS2(BS) provided on the back surface BS. Further, multiple virtual power supply lines VVDD1(BPR) of the peripheral circuit area PCA may be connected to each other through virtual power supply lines VVDD1(BS) (not illustrated) provided on the back surface BS. Note that in the other embodiments and modified examples, the interconnects of the multiple BPRs may also be connected to each other through interconnects provided on the back surface BS.

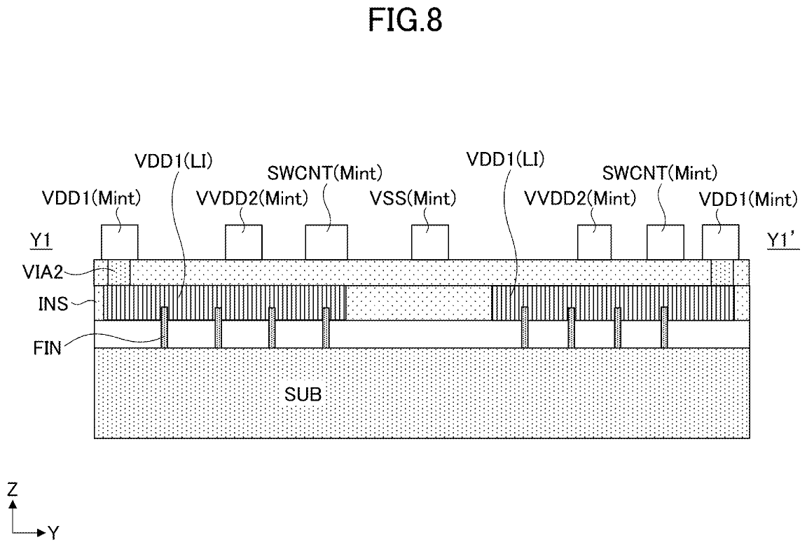

FIG. 8 is a cross-sectional view illustrating a cross section along a line Y1-Y1′ in FIG. 7. The interconnects of the Mint layer are connected to the local interconnects LI through the vias VIA2. For example, the power supply lines VDD1(Mint) are connected to the power supply lines VDD1(LI) through the vias VIA2 and further connected to the fins FIN as part of the switch transistor SWT. The fins FIN is provided on the semiconductor substrate SUB.

FIG. 9 is a cross-sectional view illustrating a cross section along a line Y2-Y2′ in FIG. 7. For example, the power supply lines VDD1(Mint) are connected to the power supply lines VDD1(BS) provided on the back surface BS of the semiconductor substrate SUB through the vias VIA2, the local interconnect LI, the vias VIA3, the BPR, and the TSVs. In addition, the ground line VSS(Mint) is connected to the ground line VSS(BPR) through the via VIA2, the local interconnect LI, and the via VIA3. Note that the power supply lines VDD1(Mint) and the power supply lines VDD1(BPR) may be connected through the vias VIA without going through the local interconnect LI. Similarly, the ground line VSS(Mint) and the ground line VSS(BPR) may be connected through the via VIA without going through the local interconnect LI.

FIG. 10 is a plan view illustrating a modified example of the layout illustrated in FIG. 7. Elements that are substantially the same as in FIG. 7 are assigned the same reference numerals or the same patterns, and detailed description thereof is omitted. FIG. 10 illustrates substantially the same layout as FIG. 7 except that the virtual power supply lines VVDD2 of the bit cell area BCA are provided using the BPR.

In the separating area SPA, the virtual power supply line VVDD(Mint) connected to the drain of the p-channel transistor P is connected to the virtual power supply line VVDD1(BPR) of the peripheral circuit area PCA and the virtual power supply line VVDD2(BPR) of the bit cell area BCA. The virtual power supply line VVDD2(BPR) is an example of a fourth power supply line.

For example, in the peripheral circuit area PCA, the virtual power supply line VVDD(Mint) is connected to the virtual power supply line VVDD1(LI) through the via VIA2 and to the virtual power supply line VVDD1(BPR) through the via VIA3. In addition, in the bit cell area BCA, the virtual power supply line VVDD(Mint) is connected to the virtual power supply line VVDD2(BPR) through the via VIA2, the local interconnect LI, and the via VIA3. Note that in the bit cell area BCA, the virtual power supply line VVDD(Mint) may be connected to the virtual power supply line VVDD2 (BPR) through the via VIA without going through the local interconnect LI.

Note that in FIG. 10, the multiple virtual power supply lines VVDD2(BPR) provided in the bit cell area BCA may be connected to each other through the virtual power supply lines VVDD(BS) (not illustrated) provided in the back surface BS of the semiconductor substrate SUB. In addition, in FIGS. 3, 4, 7, and 10, the power switch circuit PSW1 that supplies the power supply voltage to the virtual power supply line VVDD1 of the peripheral circuit area PCA may be provided in the peripheral circuit area PCA. In this case, the power switch circuit PSW provided in the separating area SPA may supply the power supply voltage only to the virtual power supply line VVDD2 of the bit cell area BCA.

In addition, the position of the virtual power supply line VVDD1(BPR) of the peripheral circuit area PCA in the Y-direction may be set to be the same as the position of the virtual power supply line VVDD2 (BPR) of the bit cell area BCR in the Y-direction. In addition, the interconnects of the BPR of the bit cell area BCA and the interconnects of the BPR of the peripheral circuit area PCA may be arranged to be shifted in the Y direction as illustrated in FIG. 4.

As above, in this embodiment, the power switch circuit PSW (or PSW1 and PSW2) can be arranged in the SRAM in which the ground lines VSS (e.g., VSS1 and VSS2) and the power supply lines VDD (e.g., VDD1) are routed to the back surface BS of the semiconductor substrate SUB.

By arranging the power switch circuit PSW in the separating area SPA, the layout sizes of the peripheral circuit area PCA and the bit cell area BCA can be reduced. As a result, the chip size or layout size of the semiconductor device 100 can be reduced. By wiring the power supply line VDD, the virtual power supply lines VVDD, and the ground lines VSS of the power switch circuit PSW in the separating area SPA using the Mint layer, the power switch circuit PSW can be arranged in the separating area SPA without violating layout rules of wiring in the BPR.

By supplying the power supply voltage VDD used in the power switch circuit PSW from the interconnects provided in the back surface BS, the increase in the power supply line area on the top surface side of the semiconductor substrate SUB can be suppressed.

As illustrated in FIG. 10, by wiring the virtual power supply lines VVDD2 using the BPR, the interconnect resistance can be lowered, and the supply capability of the VRPS voltage VVDD2 to the bit cell BC can be increased.

As illustrated in FIGS. 3, 7, and the like, the virtual power supply line VVDD1(BPR) and the power supply line VDD1(BPR) are arranged apart in the X direction. As illustrated in FIGS. 3, 7, and the like, the power supply line VDD1(BPR) and the ground line VSS2(BPR) are arranged apart in the X direction to have the separating area SPA sandwiched in-between. Accordingly, interconnects of the BPR can be provided without violating the layout rules of wiring in the BPR.

In the peripheral circuit area PCA, by electrically connecting the power supply line VDD1(BS) to the multiple power supply lines VDD1(BPR) in common and providing the power supply line VDD1 in a mesh shape, the power supply capability can be increased. In the peripheral circuit area PCA, by electrically connecting the ground line VSS1(BS) to the multiple ground lines VSS1(BPR) in common, the ground lines VSS1 can be provided in a mesh shape, the ground resistance can be reduced, and the power supply noise can be reduced.

In the bit cell area BCA, by electrically connecting the ground line VSS2(BS) to the multiple ground lines VSS2(BPR) in common, the ground lines VSS2 can be provided in a mesh shape, the ground resistance can be reduced, and the power supply noise can be reduced. Suppose that the multiple virtual power supply lines VVDD2(BPR) and the virtual power supply lines VVDD2(BS) are provided in the bit cell area BCA. In this case, by electrically connecting the virtual power supply line VVDD2(BS) to the multiple virtual power supply lines VVDD2(BPR) in common and providing the virtual power supply lines VVDD2 in a mesh shape, the power supply capability can be increased.

### Second Embodiment

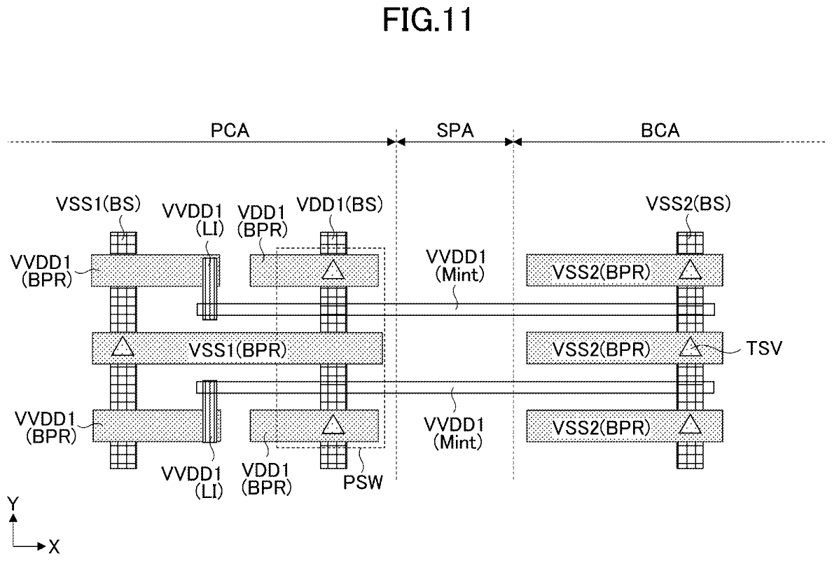

FIG. 11 is a plan view illustrating an example of a layout of power supply lines in an area where a power switch circuit of a semiconductor device in a second embodiment is arranged. Elements that are substantially the same as in FIG. 3 are assigned the same reference numerals or the same patterns. FIG. 11 is an enlarged view of an area in which the peripheral circuit area PCA and the bit cell area BCA are arranged to have the separating area SPA sandwiched in-between, and the power switch circuits PSW1 and PSW2 in FIG. 1 are arranged in the peripheral circuit area PCA as a common power switch circuit PSW.

For example, in FIG. 11, the power switch circuit PSW common to the peripheral circuit area PCA and the bit cell area BCA is arranged in the peripheral circuit area PCA, and the power switch circuit PSW is not arranged in the separating area SPA. Note that the power switch circuits PSW1 and PSW2 may be provided in each of the peripheral circuit area PCA and the bit cell area BCA as illustrated in FIG. 1. The virtual power supply lines VVDD1(Mint) of the power switch circuit PSW provided in the peripheral circuit area PCA extend to the bit cell area BCA.

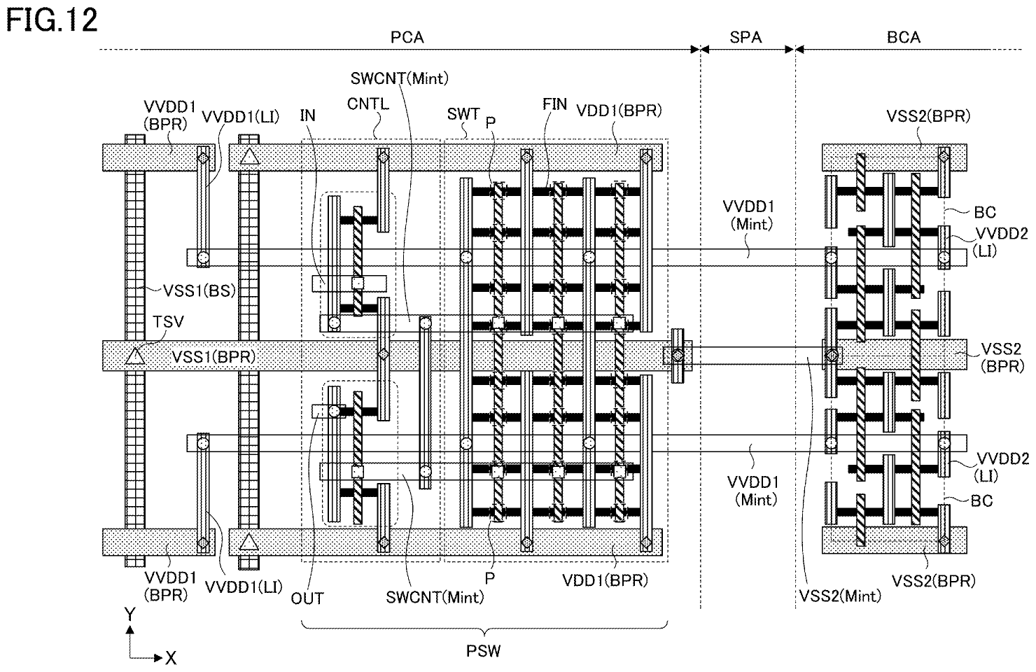

FIG. 12 is a plan view illustrating an example of the power switch circuit PSW arranged in the peripheral circuit area PCA in FIG. 11. The virtual power supply lines VVDD1(Mint) extending from the power switch circuit PSW to the bit cell area BCA are connected to the sources of the p-channel transistors P1 and P2 (FIG. 5) of the respective bit cells BC through the virtual power supply lines VVDD2(LI) in substantially the same way as in FIG. 7.

Note that in the bit cell area BCA, the virtual power supply line VVDD1(Mint) maybe connected to the virtual power supply line VVDD2(BPR), and connected to the local interconnects LI(VVDD2) through the virtual power supply line VVDD2(BPR) as illustrated in FIG. 10.

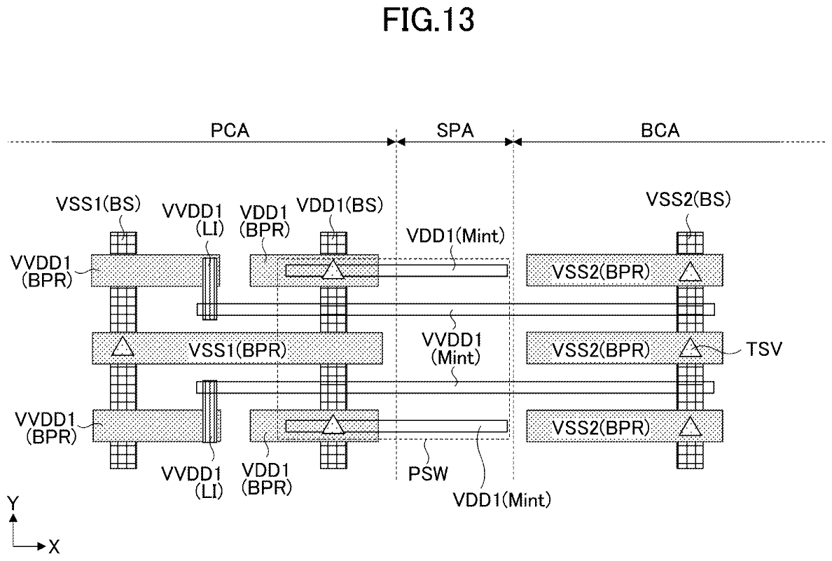

FIG. 13 is a plan view illustrating a modified example of the power switch circuit PSW in FIG. 11. Elements that are substantially the same as in FIG. 3 are assigned the same reference numerals or the same patterns. FIG. 13 illustrates substantially the same layouts as FIGS. 11 and 12 except that the power switch circuit PSW is arranged from the peripheral circuit area PCA to the separating area SPA.

The power supply lines VDD1 are routed using the BPR in the peripheral circuit area PCA and routed using the Mint layer in the separating area SPA. The power supply lines VDD1(BPR) and the power supply lines VDD1(Mint) are arranged at the same position in the Y direction and connected at positions overlapping in plan view. In FIG. 13, the description of the via VIA3, the local interconnect LI, and the via VIA2 connecting interconnects of the BPR and interconnects of the Mint layer to each other is omitted.

Note that in the bit cell area BCA, the virtual power supply lines VVDD1(Mint) may be connected to the virtual power supply lines VVDD2 (BPR), and connected to the local interconnects LI(VVDD2) through the virtual power supply lines VVDD2(BPR) as illustrated in FIG. 10.

As above, also in this embodiment, substantially the same effects as in the embodiments described above can be obtained. For example, the power switch circuit PSW can be arranged in the SRAM in which the ground line VSS (VSS1, VSS2) and the power supply line VDD (VDD1) are routed to the back surface BS of the semiconductor substrate SUB. By supplying the power supply voltage VDD used in the power switch circuit PSW from the interconnect provided in the back surface BS, the increase in the power supply line area on the top surface side of the semiconductor substrate SUB can be suppressed.

Further, in this embodiment, by arranging part of the power switch circuit PSW in the separating area SPA, the layout size of the peripheral circuit area PCA can be reduced as compared with the case where the power switch circuit PSW is arranged only in the peripheral circuit area PCA. As a result, the chip size of the semiconductor device can be reduced.

### Third Embodiment

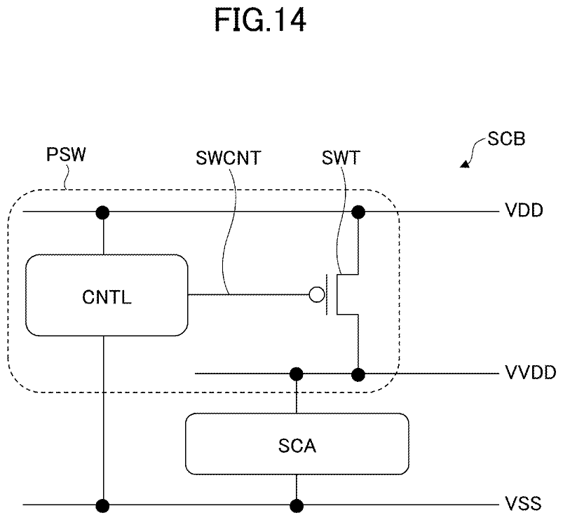

FIG. 14 is a circuit block diagram illustrating an overview of a power switch circuit PSW arranged in a standard cell block SCB of a semiconductor device in a third embodiment. Elements that are substantially the same as in FIG. 2 are assigned the same reference numerals, and detailed description thereof is omitted. FIG. 14 is substantially the same as FIG. 2, except that, instead of the SRAM, a standard cell area SCA is provided between the virtual power supply line VVDD and the ground line VSS.

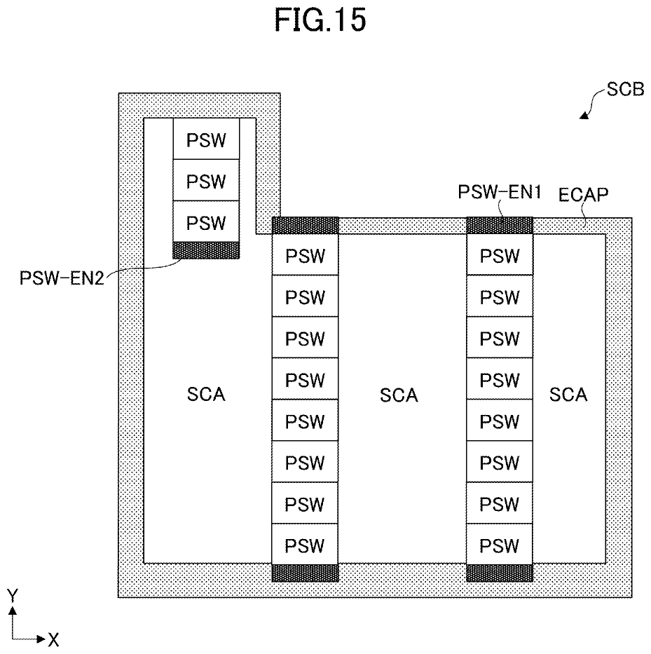

FIG. 15 is a plan view illustrating an overview of a layout of the standard cell block SCB in FIG. 14. The standard cell block SCB has the standard cell area SCA in which a circuit being a standard cell is arranged, and an end cap area ECAP arranged in the periphery of the standard cell area SCA. The end cap area ECAP is provided, for example, between the standard cell area SCA and a circuit arranged in the periphery of the standard cell area SCA, to suppress fluctuations in electrical characteristics that would occur in the case where the arrangement densities of interconnects or elements are different.

In the standard cell area SCA, multiple power switch circuits PSW are arranged side by side in the Y direction. A dummy power switch circuit PSW-EN1 is arranged at an end on the end cap area ECAP side of the power switch circuits PSW arranged in the Y direction. A dummy power switch circuit PSW-EN2 is arranged at an end on the standard cell area SCA side of the power switch circuits PSW arranged in the Y direction. In the following, the dummy power switch circuit PSW-EN1 may also be referred to as the end cap cell PSW-EN1, and the dummy power switch circuit PSW-EN2 may also be referred to as the end cap cell PSW-EN2.

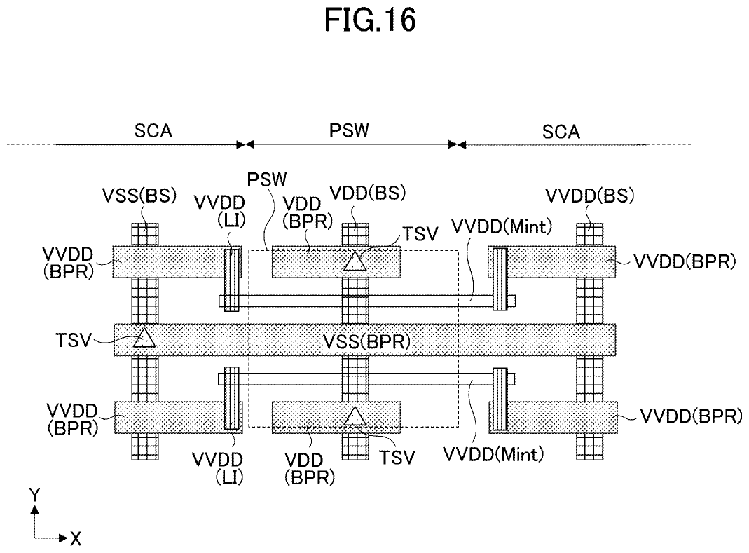

FIG. 16 is a plan view illustrating an example of a layout of power supply lines in an area where the power switch circuit PSW in FIG. 15 is arranged. Elements that are substantially the same as in FIG. 3 are assigned the same reference numerals or the same patterns. In the standard cell area SCA, the virtual power supply line VVDD(BPR) and the ground line VSS(PBR) provided using the BPR are arranged to be extending in the X direction.

In the area where the power switch circuit PSW is arranged, and the virtual power supply line VVDD(BPR) is cut and the power supply line VDD(BPR) is provided. The virtual power supply lines VVDD(BPR) cut on both sides in the X direction of the power switch circuit PSW are connected to each other through the virtual power supply line VVDD(Mint). The power switch circuit PSW has a switch transistor SWT (FIG. 14) connecting the power supply line VDD(BPR) to the virtual power supply line VVDD(Mint).

In the area where the power switch circuit PSW is arranged, multiple power supply lines VDD(BPR) arranged with spacing in the Y direction are connected to the power supply line VDD(BS) provided on the back surface BS of the semiconductor substrate SUB through the TSV. In the standard cell area SCA, the ground line VSS(BPR) is connected to the ground line VSS(BS) provided on the back surface BS through the TSV. In addition, in the standard cell area SCA, the virtual power supply line VVDD(BPR) may be connected to the virtual power supply line VVDD(BS) provided on the back surface BS through the TSV.

Note that the multiple power supply lines VDD(BPR) may be connected to each other through interconnects in the Mint layer or in a layer higher than the Mint layer, rather than interconnects of the back surface BS. The ground line VSS(BPR) may be connected to interconnects in the Mint layer or in a layer higher than the Mint layer, rather than interconnects of the back surface BS. The multiple virtual power supply lines VVVD(BPR) may be connected to each other through interconnects in the Mint layer or in a layer higher than the Mint layer, rather than interconnects of the back surface BS.

In FIG. 16, two power supply lines VVDD(BPR) are arranged in portions where each of the two virtual power supply lines VVDD(BPR) extending in the X direction is cut. In this case, for example, the number of arrangeable power supply lines VDD(BPR) can be increased as compared to the case where the power supply lines VDD(BPR) are arranged in an area provided by cutting the ground lines VSS(BPR). Accordingly, the increase in resistance of the power supply lines VDD(BPR) can be suppressed.

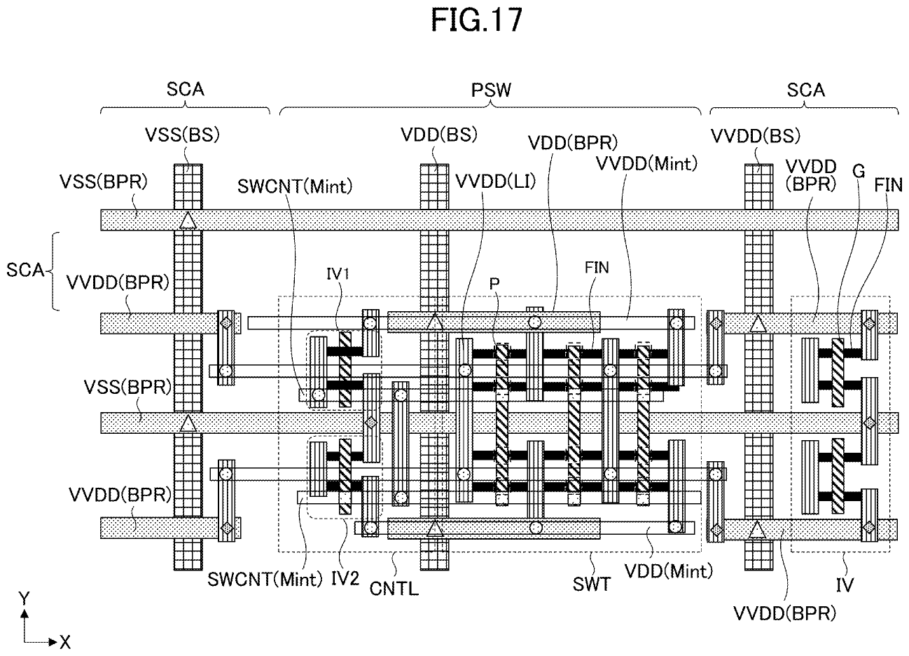

FIG. 17 is a plan view illustrating an example of a power switch circuit PSW in FIG. 16. Note that only part of the circuit in the standard cell area SCA is illustrated. In addition, the input terminals and the output terminals of the control circuit CNTL provided in the power switch circuit PSW are omitted.

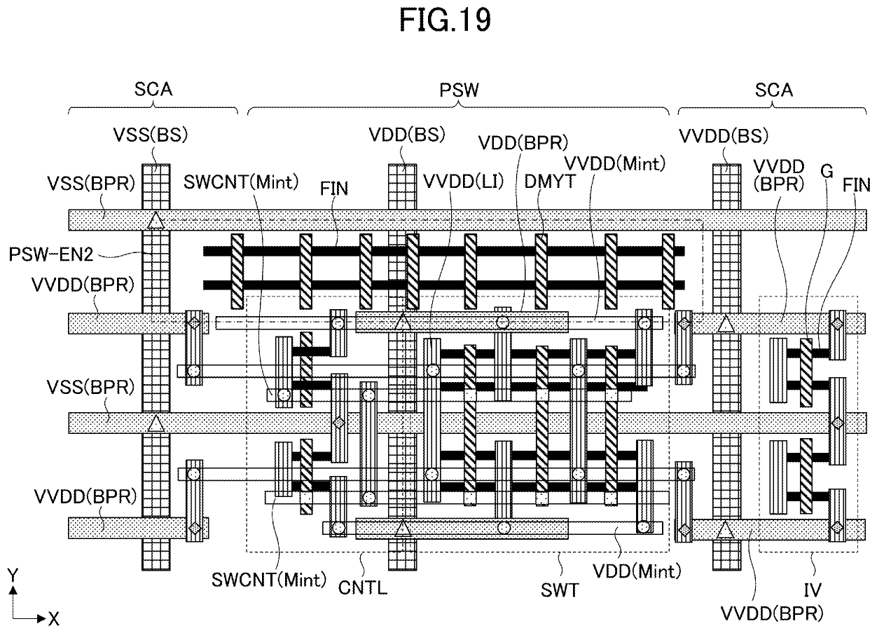

The power switch circuit PSW includes a switch transistor SWT and a control circuit CNTL as in the power switch circuit PSW illustrated in FIG. 7. However, the number of p-channel transistors P included in the switch transistor SWT is different from that in FIG. 7. Note that one or both of the end cap cells PSW-EN1 and PSW-EN2 arranged at the end of the row of the power switch circuits illustrated in FIG. 15 may have dummy transistors, dummy buffers, and the like, instead of the switch transistor SWT and the control circuit CNTL. In addition, a specific example in the case where the end cap cell PSW-EN1 or PSW-EN2 arranged to be adjacent to the power switch circuit PSW will be described in FIG. 19.

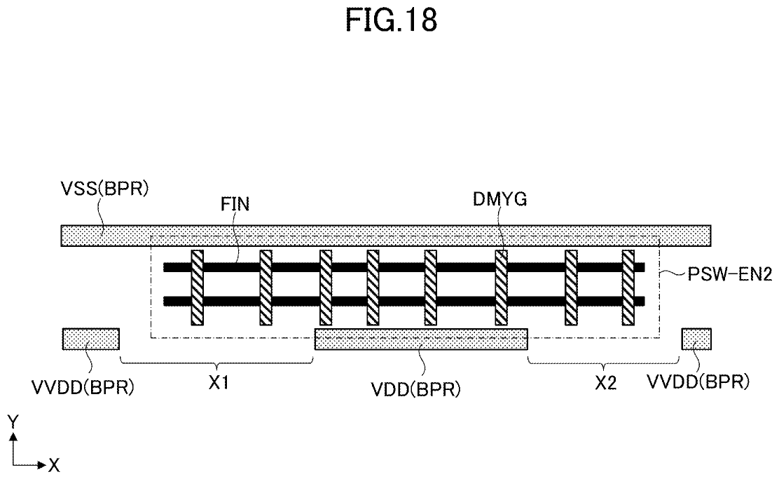

FIG. 18 is a plan view illustrating an example of the end cap cell PSW-EN2 in FIG. 15. For example, the end cap cell PSW-EN2 includes multiple dummy gates DMYG extending in the Y direction, and the multiple dummy gates DMYG are connected to a fin FIN extending in the X direction.

In addition, in the end cap cell PSW-EN2, as in the power switch circuit PSW illustrated in FIG. 17, the virtual power supply line VVDD(BPR) is cut and the power supply line VDD(BPR) is provided. The spacing X1 and X2 in the X direction between the two virtual power supply lines VVDD(BPR) and the power supply line VDD(BPR) are the same as the respective spacing between the two virtual power supply lines VVDD(BPR) and the power supply line VDD(BPR) arranged in the X direction in FIG. 17.

Accordingly, in the case where a normal standard cell is arranged to be adjacent to the power switch circuit PSW in the Y direction, a short circuit between the virtual power supply line VVDD(BPR) and the power supply line VDD(BPR) can be avoided. Note that in the case where a standard cell in which BPRs are arranged on both sides in the Y direction is arranged to be adjacent to the power switch circuit PSW in the Y direction, the virtual power supply line VVDD(BPR) and the power supply line VDD(BPR) of the power switch circuit PSW get short-circuited by the BPR of the standard cell.

FIG. 19 is a plan view illustrating an example of a case where the end cap cell PSW-EN2 in FIG. 18 is arranged to be adjacent to the power switch circuit PSW in FIG. 17. The end cap cell PSW-EN2 is arranged so that two VVDDs(BPR) and a VDD(BPR) overlap two VVDDs(BPR) and a VDD(BPR) of the power switch circuit PSW, respectively.

Accordingly, a short circuit in the power switch circuit PSW between the virtual power supply line VVDD(BPR) and the power supply line VDD(BPR) can be avoided. Note that the end cap cell PSW-EN2 in FIG. 19 has a position in the Y direction relative to the power switch circuit PSW that is opposite to the position in FIG. 15.

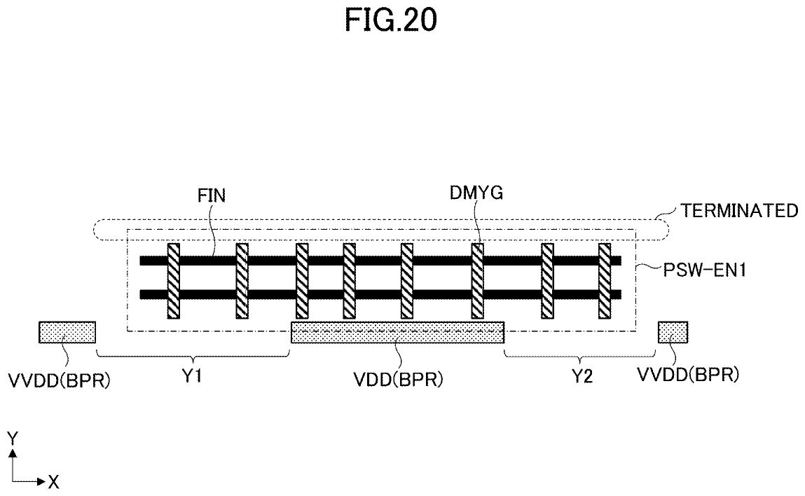

FIG. 20 is a plan view illustrating an example of the end cap cell PSW-EN1 in FIG. 15. Similar to the end cap cell PSW-EN2 illustrated in FIG. 18, the end cap cell PSW-EN1 includes multiple dummy gates DMYG extending in the Y direction, and the multiple dummy gates DMYG are connected to a fin FIN extending in the X direction.

The end cap cell PSW-EN1 can be arranged to be adjacent to the boundary of the standard cell area SCA because a side opposite to a side adjacent to the power switch circuit PSW (the dashed oval side) is terminated. Here, termination of the end cap cell PSW-EN1 is substantially the same way as termination of the other end cap cell arranged in the end cap area ECAP (FIG. 15).

As described above, also in this embodiment, substantially the same effects as in the embodiments described above can be obtained. For example, the power switch circuit PSW can be arranged in the standard cell block SCB where the ground line VSS (VSS1, VSS2) and the power supply line VDD (VDD1) are routed to the back surface BS of the semiconductor substrate SUB. By supplying the power supply voltage VDD used in the power switch circuit PSW from the interconnect provided in the back surface BS, the increase in the power supply line area on the top surface side of the semiconductor substrate SUB can be suppressed.

Further, in this embodiment, one or both of the end cap cells PSW-EN1 and PSW-EN2 are arranged at both ends of a row of the power switch circuits PSW arranged in one direction. In the end cap cell PSW-EN1, a side opposite to a side adjacent to the power switch circuit PSW is terminated in substantially the same way as the termination of the other end cap cell. Accordingly, the end cap cell PSW-EN1 may be arranged to be adjacent to the boundary of the standard cell area SCA.

In the end cap cell PSW-EN2, similar to the power switch circuit PSW, the virtual power supply line VVDD(BPR) is cut and the power supply line VDD(BPR) is provided. Accordingly, in the case where a normal standard cell is arranged to be adjacent to the power switch circuit PSW in the Y direction, a short circuit between the virtual power supply line VVDD(BPR) and the power supply line VDD(BPR) can be avoided.

As above, the present inventive concept has been described based on the respective embodiments; note that the present disclosure is not limited to the requirements set forth in the embodiments described above. These requirements can be changed to the extent that they do not depart from the gist of the present inventive concept, and can be suitably defined according to applications.

What is claimed is:

1. A semiconductor device comprising:
a substrate including a first surface and a second surface opposite to the first surface;
a first power supply line provided on the first surface;
a second power supply line provided on the first surface;
a first ground line provided on the first surface;
a third power supply line provided on the second surface;
a via provided on the substrate and electrically connecting the first power supply line and the third power supply line;
a fourth power supply line electrically connected to the second power supply line;
a second ground line provided on the first surface;
a first area including the second power supply line, the first ground line, the third power supply line, and the via;
a second area including the fourth power supply line and the second ground line;
a third area positioned between the first area and the second area in plan view; and
a power switch circuit including a switch transistor electrically connected between the first power supply line and the second power supply line.

2. The semiconductor device as claimed in claim 1, wherein the power switch circuit is provided in the third area.

3. The semiconductor device as claimed in claim 2, wherein the third area includes both a fifth power supply line electrically connected to the first power supply line and a sixth power supply line electrically connected to the second power supply line, and
wherein the switch transistor is electrically connected to the fifth power supply line and the sixth power supply line.

4. The semiconductor device as claimed in claim 1, wherein the power switch circuit is provided in the first area.

5. The semiconductor device as claimed in claim 1, wherein the first area includes a plurality of first ground lines extending in a first direction in plan view and arranged with spacing in a second direction different from the first direction in plan view,
wherein the second area includes a plurality of second ground lines extending in the first direction and arranged with spacing in the second direction, and
wherein arrangement spacing of the plurality of first ground lines in the second direction is different from arrangement spacing of the plurality of second ground lines in the second direction.

6. The semiconductor device as claimed in claim 1, wherein the first power supply line and the second power supply line extend in a first direction, and are arranged apart from each other in the first direction in plan view.

7. The semiconductor device as claimed in claim 6, wherein the first power supply line, the second power supply line, and the fourth power supply line are arranged apart from each other in the first direction in plan view.

8. The semiconductor device as claimed in claim 1, wherein the third power supply line is electrically connected to a plurality of first power supply lines in common.

9. The semiconductor device as claimed in claim 1, further comprising:
a third ground line provided on the second surface of the first area and electrically connected to a plurality of first ground lines in common; and
a fourth ground line provided on the second surface of the second area and electrically connected to a plurality of second ground lines in common.

10. The semiconductor device as claimed in claim 1, wherein the second power supply line and the fourth power supply line extending in a first direction differ from each other in positions in a second direction different from the first direction, and
wherein the second power supply line and the fourth power supply line are connected to each other through a first interconnect.

11. The semiconductor device as claimed in claim 1, wherein the fourth power supply line is provided on the first surface.
